(19) United States
(12) Patent Application Publication
(10) Pub. No.: US 2024/0367391 A1
(43) Pub. Date: Nov. 7, 2024

(54) STITCHED ELECTROMAGNETIC WAVE ABSORBING COMPOSITE MATERIAL FOR LOW-SPEED IMPACT PROTECTION

(71) Applicant: Industry-Academic Cooperation Foundation Gyeongsang National University, Gyeongsangnam-do (KR)

(72) Inventors: Young Woo Nam, Gyeonggi-do (KR); Jin Ho CHOI, Gyeongsangnam-do (KR); Byeong Su KWAK, Gyeongsangnam-do (KR); Uy Hwa SEO, Gyeongsangnam-do (KR); Woo Jin AN, Gyeongsangnam-do (KR); Ji Sub NOH, Gyeongsangnam-do (KR); Dong Jun HONG, Busan (KR)

(73) Assignee: Industry-Academic Cooperation Foundation Gyeongsang National University, Gyeongsangnam-do (KR)

(21) Appl. No.: 18/688,547

(22) PCT Filed: Nov. 18, 2021
(86) PCT No.: PCT/KR2021/017002

§ 371 Date: May 16, 2024

(30) Foreign Application Priority Data
Sep. 3, 2021 (KR) 10-2021-0117734

(51) Int. Cl. B29C 70/22; B29K 63/00; B29K 105/08; B29K 309/08

(52) U.S. Cl. CPC B29C 70/22; B29K 2063/00; B29K 2105/089; B29K 2309/08; B29K 2995/0003; B29K 2995/0089

(57) ABSTRACT

The present disclosure relates to a stitched electromagnetic wave-absorbing composite for low-speed impact protection, and particularly, to a composite that exhibits electromagnetic wave absorption performance and low-speed impact protection performance at the same time by applying a stitching method, a thickness direction reinforcement method, to a composite that is an electromagnetic wave absorber. The present disclosure provides a stitched electromagnetic wave-absorbing composite for low-speed impact protection including a composite composed of at least one of glass fiber, epoxy, or glass fiber reinforced plastics (GFRP) in an electromagnetic wave-absorbing composite, wherein the composite absorbs electromagnetic waves, and has an impact protection system applied thereto through stitching.

### TECHNICAL FIELD

The present disclosure relates to a stitched electromagnetic wave-absorbing composite for low-speed impact protection, and particularly, to a composite that exhibits electromagnetic wave absorption performance and low-speed impact protection performance at the same time by applying a stitching method, a thickness direction reinforcement method, to a composite that is an electromagnetic wave absorber.

### BACKGROUND ART

Recently, the use of composite materials in many aircraft structures has been increasing due to the need for performance improvement, weight reduction, etc. of aircrafts. However, in the anisotropic material properties of composite materials, their use is subject to many limitations due to complex mechanical behaviors, damage patterns, etc. Aircrafts are exposed to external impacts such as hail and bird strikes that may occur during operation. Such impacts belong to low-speed impacts that impact at a speed of 30 m/s or less. Since damages caused by low-speed impacts are not apparent in external appearance, they may bring about fatal structural defects when they develop along with barely visible impact damages (BVID).

Meanwhile, an interlayer separation phenomenon in which each layer separates due to impact load occurs in aircraft shells fabricated of composites, and interlayer separation is a structural defect, and when it occurs, the soundness of the designed composite structure may not be secured. For this reason, much research and invention is being conducted on various thickness direction reinforcement methods that can prevent damages caused by low-speed impacts.

However, currently ongoing research has focused only on fabricating structures with excellent electromagnetic wave absorption performance, and progress in research to exhibit the impact protection performance of electromagnetic wave-absorbing structures implemented with composites is insignificant. Structures that are vulnerable to layer separation have a fatal weakness that reduces electromagnetic wave absorption performance, so technology for electromagnetic wave-absorbing composite structures to which impact protection systems are applied is essentially needed.

### DISCLOSURE

### Technical Problem

The present disclosure is intended to solve the above-mentioned problems, and an object of the present disclosure is to provide an absorbent composite that exhibits excellent electromagnetic wave absorption performance in a target frequency band and at the same time has an impact protection system applied thereto through a composite material continuous stitching method.

### Technical Solution

In order to achieve the above object, the present disclosure provides a stitched electromagnetic wave-absorbing composite for low-speed impact protection including a composite composed of at least one of glass fiber, epoxy, or glass fiber reinforced plastics (GFRP) in an electromagnetic wave-absorbing composite, wherein the composite absorbs electromagnetic waves, and has an impact protection system applied thereto through stitching.

According to an embodiment, the composite may maintain electromagnetic wave absorption performance even after the low-speed impacts.

According to an embodiment, the composite may further include: dielectric fibers composed of aramid fibers, silicon carbide (SiC), glass, organic fibers, or quartz; or metal electroless plated dielectric fibers.

According to an embodiment, the composite may further include: a first layer composed of nickel-coated glass fiber or epoxy; and a second layer composed of glass fiber or epoxy.

According to an embodiment, the stitching may be applied by continuously disposing aramid fibers at 6 mm intervals in the warp direction of the electromagnetic wave-absorbing composite and spacing them at 6 mm intervals in the fill direction.

According to an embodiment, the composite may exhibit an absorbency of −10 dB or less when it is operated as an absorber of incident electromagnetic waves in the range of 8.2 GHz to 12.4 GHz.

### Advantageous Effects

According to the present disclosure having the configuration described above, there is an advantage in that the structure of the dedicated equipment is simplified through a composite material continuous stitching method using a hollow needle and the structure can be applied in a single direction, making it easy to apply.

In addition, the present disclosure has an advantage of showing excellent electromagnetic wave absorption performance in the target frequency band.

### BRIEF DESCRIPTION OF DRAWINGS

FIG. 1 shows the Dallenbach layer structure applied to the present disclosure.

FIG. 2 shows a composite design structure diagram according to an embodiment of the present disclosure.

FIG. 3 shows complex permittivities of a dielectric fiber and a nickel electroless plated dielectric fiber according to an embodiment of the present disclosure.

FIG. 4 shows (a) scanning electron microscope (SEM) images, (b) focused ion beam milling combined with scanning electron microscope (FIB-SEM) images, (c) X-ray photoelectron spectroscopy (XPS) measurement results, and (d) energy-dispersive X-ray spectroscopy (EDS) component analysis results of a nickel electroless plated dielectric fiber according to an embodiment of the present disclosure.

FIG. 5 shows electromagnetic wave absorption performance design and test results of (a) an unstitched composite and (b) a stitched composite according to an embodiment of the present disclosure.

FIG. 6 shows a fabrication process of an electromagnetic wave-absorbing composite to which stitching is applied according to an embodiment of the present disclosure.

FIG. 7 shows an impact test set-up according to an embodiment of the present disclosure.

FIG. 8 shows (a) damage photos, (b) C-scan images, and (c) X-ray micro-CT measurement results of an electromagnetic wave-absorbing composite structure depending on whether or not the stitching process is applied according to an embodiment of the present disclosure.

FIG. 9 shows 1D return loss scanning results at 10 GHz of an electromagnetic wave-absorbing composite structure depending on whether or not the stitching process is applied according to an embodiment of the present disclosure.

FIG. 10 shows (a) a post-impact compression property test set-up, (b) an unstitched specimen failure mode, and (c) a stitched specimen failure mode according to an embodiment of the present disclosure.

FIG. 11 shows compression properties after impact of an electromagnetic wave-absorbing structure depending on whether or not the stitching process is applied according to an embodiment of the present disclosure.

### BEST MODE

In order to achieve the above object, the present disclosure provides a stitched electromagnetic wave-absorbing composite for low-speed impact protection including a composite composed of at least one of glass fiber, epoxy, or glass fiber reinforced plastics (GFRP) in an electromagnetic wave-absorbing composite, wherein the composite absorbs electromagnetic waves, and has an impact protection system applied thereto through stitching.

According to an embodiment, the composite may maintain electromagnetic wave absorption performance even after the low-speed impacts.

According to an embodiment, the composite may further include: dielectric fibers composed of aramid fibers, silicon carbide (SiC), glass, organic fibers, or quartz; or metal electroless plated dielectric fibers.

According to an embodiment, the composite may further include: a first layer composed of nickel-coated glass fiber or epoxy; and a second layer composed of glass fiber or epoxy.

According to an embodiment, the stitching may be applied by continuously disposing aramid fibers at 6 mm intervals in the warp direction of the electromagnetic wave-absorbing composite and spacing them at 6 mm intervals in the fill direction.

According to an embodiment, the composite may exhibit an absorbency of −10 dB or less when it is operated as an absorber of incident electromagnetic waves in the range of 8.2 GHz to 12.4 GHz.

### MODE FOR INVENTION

Hereinafter, terms used in this specification will be briefly explained, and the configuration and operation of a preferred embodiment of the present disclosure will be described in detail as specific details for carrying out the present disclosure.

The terms used in this specification have selected general terms that are currently widely used as much as possible while considering the function in the present disclosure, but this may vary depending on the intention or precedent of a person skilled in the art, the emergence of new technology, etc. In addition, in specific cases, there are also terms arbitrarily selected by the applicant, and in this case, the meaning will be described in detail in the description of the relevant invention. Therefore, the terms used in the present disclosure should be defined based on the meanings of the terms and the overall contents of the present disclosure, rather than simply the names of the terms.

When it is said that a part “includes” a certain element throughout the specification, this means that, unless specifically stated to the contrary, it does not exclude other elements but may further include other elements. In addition, terms such as “ . . . unit” and “module” described in the specification refer to a unit that processes at least one function or operation, which may be implemented as hardware or software, or as a combination of hardware and software. In addition, when a part is said to be “connected” to another part throughout the specification, this includes not only cases where it is “directly connected thereto,” but also cases where it is connected thereto “with another component being in the middle therebetween.”

Below, embodiments of the present disclosure will be described in detail so that those skilled in the art to which the present disclosure pertains can easily implement the present disclosure with reference to the attached drawings. However, the present disclosure may be implemented in many different forms and is not limited to the embodiments described herein. In addition, parts not related to the description are omitted, and similar parts are given similar reference numerals throughout the specification in order to clearly explain the present disclosure in the drawings.

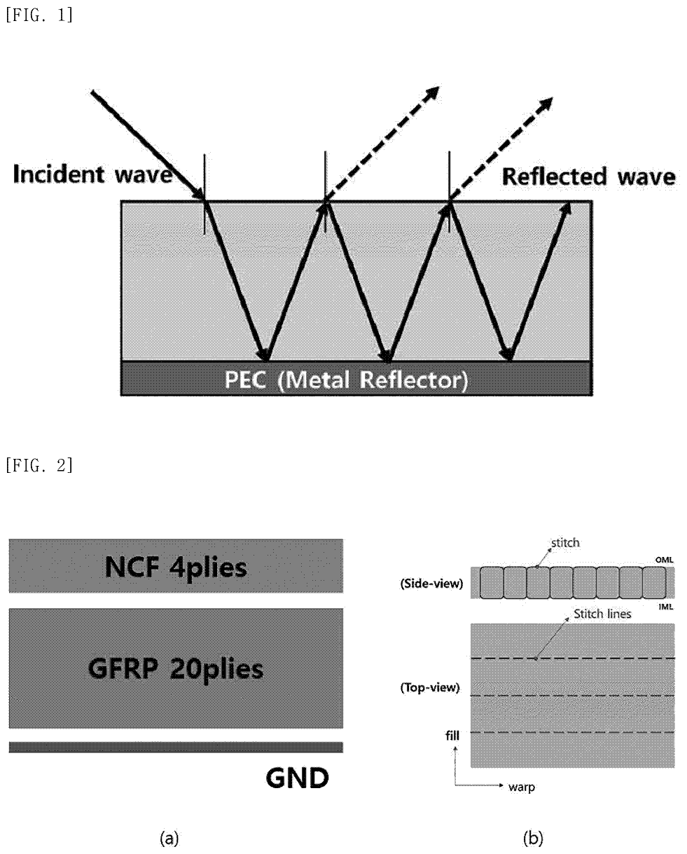

FIG. 1 shows the Dallenbach layer structure applied to the present disclosure.

Referring to FIG. 1, the configuration of the composite of the present disclosure can be seen, and particularly it can be seen that the composite of the present disclosure has a configuration of an electromagnetic wave-absorbing structure to which a designed two-layer type impact protection system is applied.

The composite of the present disclosure may include a first layer composed of nickel-coated glass fiber or epoxy and a second layer composed of glass fiber or epoxy.

According to an embodiment, a two-layer type impact protection system may be applied, the first layer may be formed to 0.502 mm (nickel-coated glass fiber/epoxy), and the second layer may be formed to 2.479 mm (glass fiber/epoxy).

FIG. 2 shows a composite design structure diagram according to an embodiment of the present disclosure.

Referring to FIG. 2, the stitching process applied to the present disclosure can be confirmed.

According to an embodiment, the electromagnetic wave-absorbing composite of the present disclosure includes a composite composed of at least one of glass fiber, epoxy, or glass fiber reinforced plastics (GFRP), wherein the composite may absorb electromagnetic waves, and have an impact protection system applied thereto through stitching.

Here, the composite may maintain electromagnetic wave absorption performance even after low-speed impacts, and may include dielectric fibers composed of aramid fibers, silicon carbide (SiC), glass, organic fibers, or quartz; or metal electroless plated dielectric fibers.

The present disclosure is a composite structure to which electromagnetic wave absorption and impact protection systems are applied by applying a stitching method of reinforcing the composite in the thickness direction to an electromagnetic wave-absorbing composite structure. The electromagnetic wave absorption performance was implemented by designing a composite structure composed of dielectric fibers and metal-coated dielectric fibers.

The impact protection system of the present disclosure was implemented by applying a composite continuous stitching process to the designed electromagnetic wave-absorbing structure, which does not affect the electromagnetic wave absorption performance and serves to suppress interlayer separation within the composite due to impact.

In order to design the optimal electromagnetic wave-absorbing structure, the permittivity of the metal-coated dielectric fiber was measured and designed using the electromagnetic wave absorption analysis program (CST STUDIO) based on this data.

In the present disclosure, the performance of an electromagnetic wave absorber was designed and fabricated to exhibit electromagnetic wave absorption performance of 90% or more in the X-band (8.2 to 12.4 GHz) band, and the performance of the electromagnetic wave absorber was verified by measuring return loss. The return loss measurement-completed absorber was verified for impact protection performance through an impact test.

Return loss may be represented by Mathematical Equation 1 below.

$$Return loss = 10 log {\vert \frac{{Z}_{in} - {Z}_{o}}{{Z}_{in} + {Z}_{o}} \vert}^{2} = 10 log {Γ}^{2} \qquad [ Mathematical Equation 1 ]$$

(Where, Γ: return loss coefficient, Zₘ=incident impedance, and Zₒ=free space impedance=377Ω)

The electromagnetic wave-absorbing composite structure of the present disclosure may be implemented as the Dallenbach layer of FIG. 1 and may be designed and fabricated as a two-layer type composite structure. It is composed of regular glass fiber/epoxy, nickel-coated glass fiber/epoxy, and a dielectric fiber reinforced in the thickness direction, and when using Maxwell's Law equation, the characteristic impedance may be represented by Mathematical Equation 2, and the propagation constant may be represented by Mathematical Equation 3.

$${Z}_{c} = {Z}_{o} \sqrt{\frac{{μ}_{r}}{{ε}_{r}}} \qquad [ Mathematical Equation 2 ]$$

$${r}_{c} = j \frac{2 π}{λ} \sqrt{{ε}_{r} {μ}_{r}} \qquad [ Mathematical Equation 3 ]$$

(Here, Z_{L} becomes the characteristic impedance of the metal plate, so Z_{L}=0, and if the electromagnetic wave-absorbing structure is fabricated using a dielectric material, μᵣ=1. Also, since Zᵢₙ=Zₒ in which the input impedance is the same as the impedance of free space, the thickness with optimal electromagnetic wave absorption performance causing impedance matching was calculated through Mathematical Equation 4 below).

$$1 = \frac{1}{\sqrt{{ε}_{r}}} tan j \frac{2 π d}{λ} \sqrt{{ε}_{r}} \qquad [ Mathematical Equation 4 ]$$

FIG. 3 shows complex permittivities of a dielectric fiber and a nickel electroless plated dielectric fiber according to an embodiment of the present disclosure.

In order to implement an electromagnetic wave-absorbing composite structure to which stitching was applied, regular dielectric fibers, nickel electroless plated dielectric fibers, and aramid fibers were used in stitching. At 10 GHz, the dielectric fibers have a complex permittivity of 4.57-j0.05, and the nickel electroless plated dielectric fiber has a complex permittivity of 5.77-j6.6. For chemical crystal analysis of nickel electroless plated dielectric fibers, SEM images, FIB-SEM images, EDS component analysis, and XPS measurement were performed. It was confirmed that nickel was uniformly coated on the surface of the dielectric fibers through the SEM images, and it was confirmed that the Ni component content on the fiber surface increased through EDS component analysis. Through XPS measurement, the Ni component peak was checked at 856.1 eV. This is consistent with the value of the nickel binding energy ranging from 855.6 to 857.9 eV, and maintains the divalent oxidation state. Impact protection function stitching was applied and designed at 6 mm intervals.

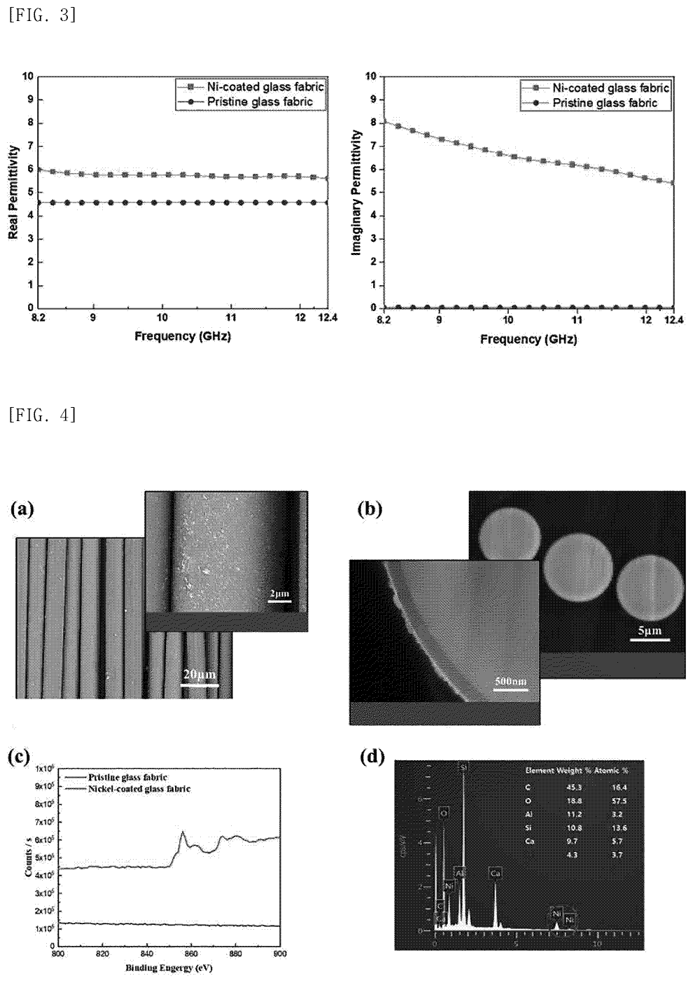

FIG. 4 shows (a) scanning electron microscope (SEM) images, (b) focused ion beam milling combined with scanning electron microscope (FIB-SEM) images, (c) X-ray photoelectron spectroscopy (XPS) measurement results, and (d) energy-dispersive X-ray spectroscopy (EDS) component analysis results of a nickel electroless plated dielectric fiber according to an embodiment of the present disclosure.

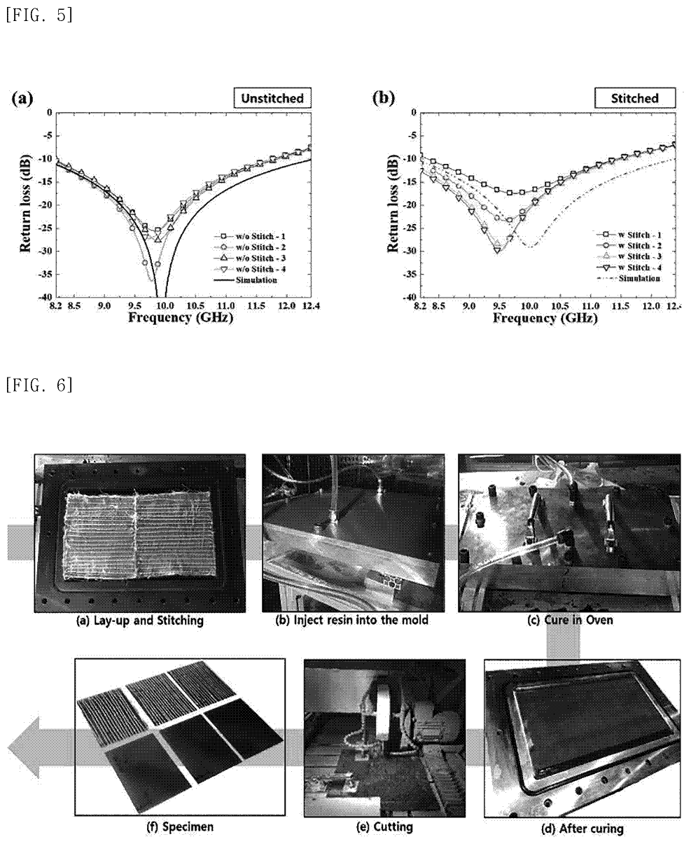

In the case of FIG. 5, in order to evaluate the electromagnetic wave absorption performance of an electromagnetic wave-absorbing composite structure to which stitching is applied, it shows an appearance in which the electromagnetic wave-absorbing composite structure to which stitching is applied is designed, and analysis thereof is performed through the CST Studio program.

FIG. 5 shows electromagnetic wave absorption performance design and test results of (a) an unstitched composite and (b) a stitched composite according to an embodiment of the present disclosure.

Referring to FIGS. 4 and 5, the electromagnetic wave absorption performance analysis results of the electromagnetic wave-absorbing composite structure to which stitching is applied depending on whether or not stitching is applied are shown in FIG. 5. The electromagnetic wave-absorbing sandwich composite structure showed absorption performance of −10 dB or less (absorption performance of 90% or more) in the 8.2 to 12.4 GHz band.

FIG. 6 shows a fabrication process of an electromagnetic wave-absorbing composite to which stitching is applied according to an embodiment of the present disclosure.

In the case of FIG. 6, it shows a fabrication process of an electromagnetic wave-absorbing composite to which a stitching process for impact protection is applied, and in order to minimize damage to the composite material due to needle insertion during the stitching process and maximize the reinforcement effect, the stitching was applied by continuously disposing aramid fibers at 6 mm intervals in the warp direction of the electromagnetic wave-absorbing composite and spacing them at 6 mm intervals in the fill direction.

The process for fabricating the specimen used the resin transfer molding (RTM) process so that specimens of the same thickness are ensured at all times, and the fabrication mold was designed and fabricated accordingly. After curing, the panel was cut with a diamond cutting wheel, and five specimens for each test item were secured.

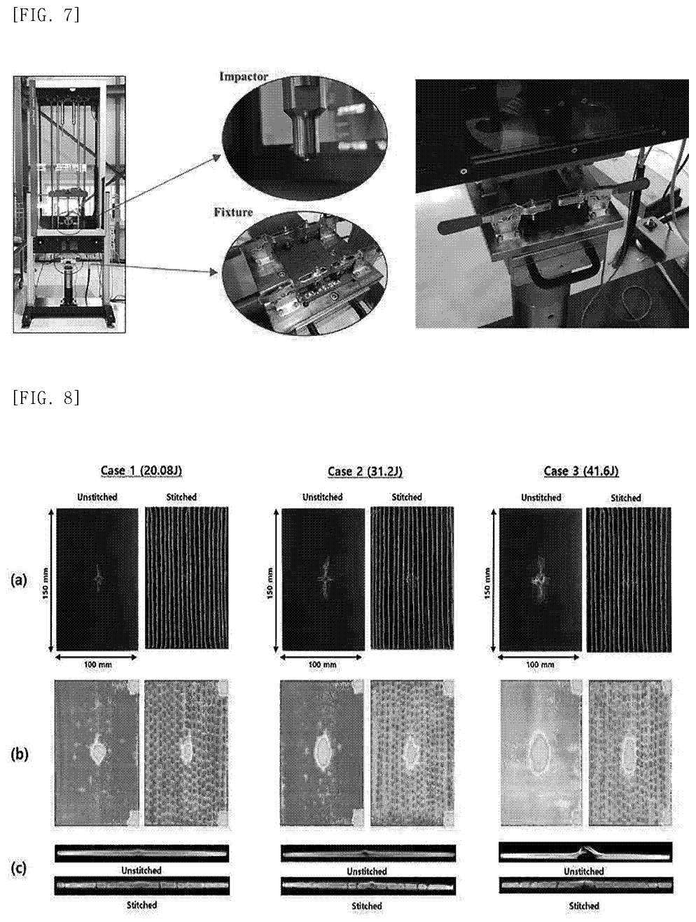

FIG. 7 shows an impact test set-up according to an embodiment of the present disclosure.

In the case of FIG. 7, it is an appearance in which an impact test was performed using an impact tester (HIT600F, Zwick/Roell Co.) in order to evaluate the impact protection performance of the electromagnetic wave-absorbing composite structure to which stitching was applied.

According to an embodiment of the present disclosure, an impact energy of 20.8 J was applied based on the ASTM D7136 standard, and impact energies of 31.2 J and 41.6 J were additionally applied in order to evaluate performance at higher impact energies.

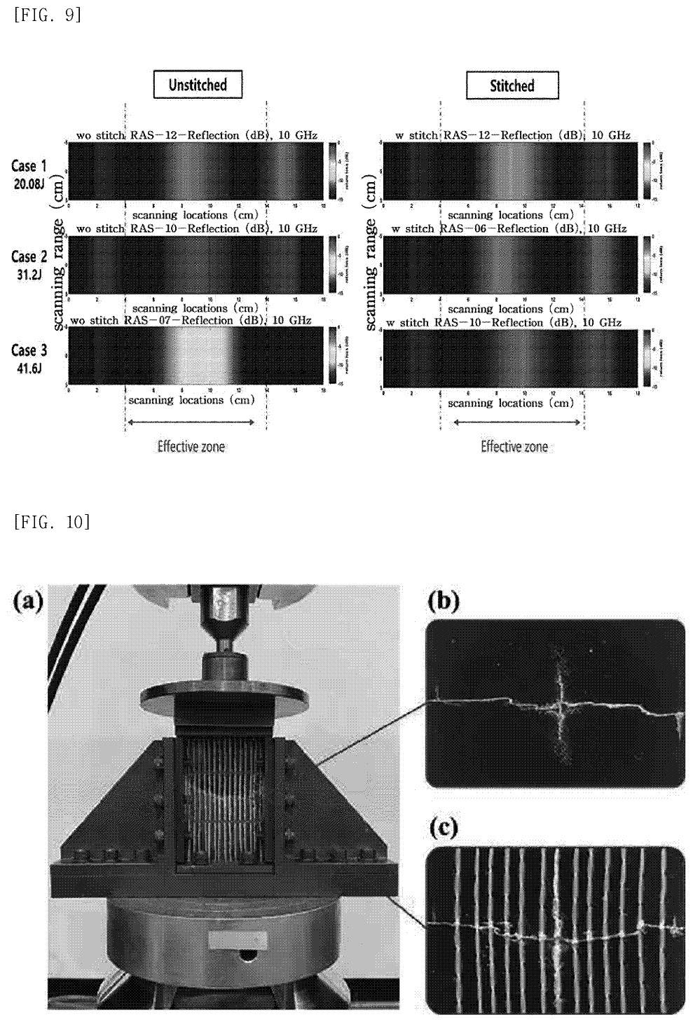

FIG. 8 shows (a) damage photos, (b) C-scan images, and (c) X-ray micro-CT measurement results of an electromagnetic wave-absorbing composite structure depending on whether or not the stitching process is applied according to an embodiment of the present disclosure.

Referring to FIG. 8, an appearance in which non-destructive inspection of both C-scan and X-ray micro-CT inspection was performed in order to evaluate the degree of damage for each impact energy after the impact test can be seen.

In particular, C-scan imaging, which quantitatively indicates the attenuation rate of ultrasonic dB, was performed in order to measure the in-plane damaged area, and additionally, 3D X-ray CT imaging was performed in order to measure the degree of damage in the thickness direction.

It can be visually confirmed that the damaged depth of the specimen to which stitching is not applied is large, and the damaged area and depth were analyzed and quantitatively evaluated from each C-scan and X-ray micro-CT measurement result as shown in Table 1 below.

TABLE 1

| | | Impact | Damaged area | Damaged |
|---|---|---|---|---|
| | Type of RAS | energy (J) | (mm²) | depth (mm) |
| Case 1 | Unstitched | 20.8 | 246.4 | 0.54 |
| | RAS | | | |
| | Stitched RAS | 20.8 | 206.3 | 0.32 |
| Case 2 | Unstitched | 31.2 | 473.0 | 0.95 |
| | RAS | | | |
| | Stitched RAS | 31.2 | 366.6 | 0.45 |
| Case 3 | Unstitched | 41.6 | 645.4 | 3.90 |
| | RAS | | | |
| | Stitched RAS | 41.6 | 486.0 | 0.88 |

In the electromagnetic wave-absorbing composite structure to which stitching is applied, the reinforcing fibers strengthen the bond between composite sheets and thus act to prevent cracks from developing after impact, so it can be confirmed that the damaged area of the specimen to which stitching was applied is small in all test items. FIG. 9 shows 1D return loss scanning results at 10 GHz of an electromagnetic wave-absorbing composite structure depending on whether or not the stitching process is applied according to an embodiment of the present disclosure.

In the case of FIG. 9, the test results of performing 1D return loss scanning using free space measuring equipment are shown in order to evaluate electromagnetic wave absorption performance depending on whether or not the stitching process is applied after impact.

In particular, it can be confirmed that the absorption performance level was lowered compared to the intact area in the case of specimens to which the stitching process was not applied at 10 GHz, and the same level of absorption performance was observed across the scan area similar to an undamaged structure in the case of the specimens to which the stitching process was applied. Through this, it was proven that the stitching process is effective in preventing mechanical and electromagnetic damages in an electromagnetic wave-absorbing composite structure to which the stitching process is applied.

FIG. 10 shows (a) a post-impact compression property test set-up, (b) an unstitched specimen failure mode, and (c) a stitched specimen failure mode according to an embodiment of the present disclosure.

FIG. 10 is an embodiment of an appearance of performing a compression test set-up according to the ASTM D7136 standard in order to evaluate the compressive strength after impact of an electromagnetic wave-absorbing composite structure to which the stitching process is applied.

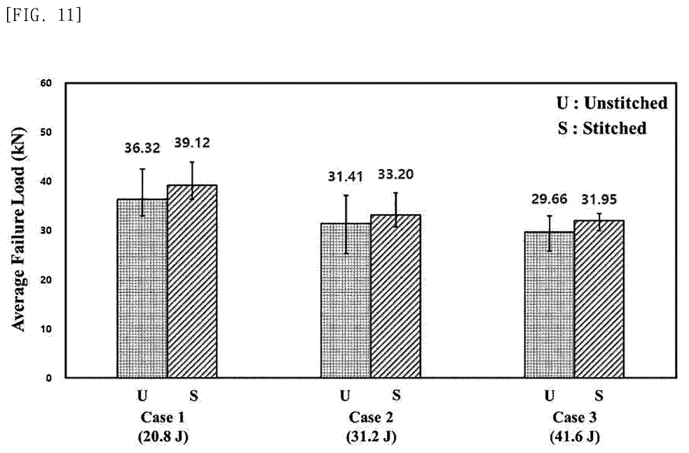

FIG. 11 shows average failure loads resulting from the compression test results after impact as compression properties after impact of an electromagnetic wave-absorbing structure depending on whether or not the stitching process is applied according to an embodiment of the present disclosure, and the average failure loads of the specimens to which the stitching process was applied in all test items were shown to be high.

The present disclosure can design and fabricate a stitched electromagnetic wave-absorbing composite that exhibits low-speed impact protection performance by improving the interlayer strength after binding the composite with dielectric fibers in the thickness direction and can maintain electromagnetic wave absorption performance even after impact.

Although the present disclosure has been described in detail through representative embodiments above, those skilled in the art to which the present disclosure pertains will understand that various modifications can be made to the above-described embodiments without departing from the scope of the present disclosure. Therefore, the scope of rights of the present disclosure should not be limited to the described embodiments, but should be determined not only by the claims described later, but also by all changes or modified forms derived from the claims and equivalent concepts.

1. A stitched electromagnetic wave-absorbing composite for low-speed impact protection comprising a composite composed of at least one of glass fiber, epoxy, or glass fiber reinforced plastics (GFRP) in an electromagnetic wave-absorbing composite,
wherein the composite absorbs electromagnetic waves, and has an impact protection system applied thereto through stitching.

2. The stitched electromagnetic wave-absorbing composite for low-speed impact protection of claim 1, wherein the composite maintains electromagnetic wave absorption performance even after the low-speed impacts.

3. The stitched electromagnetic wave-absorbing composite for low-speed impact protection of claim 1, further comprising:
dielectric fibers composed of aramid fibers, silicon carbide (SiC), glass, organic fibers, or quartz; or
metal electroless plated dielectric fibers.

4. The stitched electromagnetic wave-absorbing composite for low-speed impact protection of claim 1, further comprising:
a first layer composed of nickel-coated glass fiber or epoxy; and
a second layer composed of glass fiber or epoxy.

5. The stitched electromagnetic wave-absorbing composite for low-speed impact protection of claim 1, wherein the stitching is applied by continuously disposing aramid fibers at 3 to 12 mm intervals in the warp direction of the electromagnetic wave-absorbing composite and spacing them at 3 to 12 mm intervals in the fill direction.

6. The stitched electromagnetic wave-absorbing composite for low-speed impact protection of claim 1, wherein the composite exhibits an absorbency of −10 dB or less when it is operated as an absorber of incident electromagnetic waves in the range of 8.2 GHz to 12.4 GHz.
